(19) United States
(12) Patent Application Publication
(10) Pub. No.: US 2024/0401192 A1
(43) Pub. Date: Dec. 5, 2024

(54) REMOTE SOLID REFILL CHAMBER

(71) Applicant: ASM IP Holding B.V., Almere (NL)

(72) Inventors: Eric James Shero, Phoenix, AZ (US); Paul Ma, Scottsdale, AZ (US); Jereld Lee Winkler, Gilbert, AZ (US); Todd Robert Dunn, Cave Creek, AZ (US); Shuaidi Zhang, Chandler, AZ (US); Jacqueline Wrench, Mesa, AZ (US); Shubham Garg, Gilbert, AZ (US); Jonathan Bakke, Phoenix, AZ (US)

(21) Appl. No.: 18/675,851

(22) Filed: May 28, 2024

Related U.S. Application Data
(60) Provisional application No. 63/470,024, filed on May 31, 2023.

(51) Int. Cl. C23C 16/448; C23C 16/455; C23C 16/52

(52) U.S. Cl. CPC C23C 16/448; C23C 16/45557; C23C 16/45561; C23C 16/52

(57) ABSTRACT

Various examples of the present disclosure relate to methods, systems, and apparatus for coupling a delivery vessel disposed at a first location on a substrate processing platform to a remote refill vessel disposed in a second location remote from the substrate processing platform, storing a chemical in the remote refill vessel in a first phase, changing the chemical in the remote refill vessel to a second phase, transporting the chemical in the second phase, to the delivery vessel, maintaining a temperature gradient within an inner volume of the delivery vessel, and returning the chemical to the first phase within the inner volume.

### CROSS-REFERENCE TO RELATED APPLICATIONS

This application is a nonprovisional of, and claims priority to and the benefit of, U.S. Provisional Patent Application No. 63/470,024, filed May 31, 2023 and entitled “REMOTE SOLID REFILL CHAMBER,” which is hereby incorporated by reference herein.

### FIELD OF THE DISCLOSURE

The present disclosure relates generally to semiconductor processing equipment and specifically to a method, system and apparatus for refilling a chemical precursor delivery vessel.

### BACKGROUND OF THE DISCLOSURE

Semiconductor manufacturing processes such as chemical vapor deposition (CVD) and atomic layer deposition (ALD) involve deposition of thin film on a semiconductor wafer (also referred to herein as a “substrate”). During processing, the wafer is exposed to one or more precursors in a reaction chamber to deposit the thin layers of material. The precursor source is typically stored in delivery vessels onboard a processing tool and delivered to the reaction chamber from the delivery vessels. In order to reduce the need to service and change out delivery vessels delivery vessels are being made progressively larger. However, even large delivery vessels eventually empty and need to be swapped out requiring down-time and possibly quality or safety excursions. Such systems have generally been accepted for their intended purpose.

However, there remains a need for improved methods, systems and apparatus for reducing the need to service and change out delivery vessels. The present disclosure provides a solution to this need.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods, systems, and apparatus for coupling a delivery vessel disposed at a first location on a substrate processing platform to a remote refill vessel disposed in a second location remote from the substrate processing platform, storing a chemical in the remote refill vessel in a first phase, changing the chemical in the remote refill vessel to a second phase, transporting the chemical in the second phase, to the delivery vessel, maintaining a temperature gradient within an inner volume of the delivery vessel, and returning the chemical to the first phase within the inner volume.

In accordance with various examples of the disclosure, the first phase may be a solid and the second phase may be a gas and wherein the maintaining the temperature gradient further comprises controlling a heating device disposed at a top portion of the delivery vessel or controlling a cooling device disposed at a bottom portion of the delivery vessel or a combination thereof, responsive to sensor data received from one or more temperature sensors inside the delivery vessel, and solidifying the chemical within the inner volume at least at a bottom surface of the delivery vessel.

In some examples, controlling the heating device disposed at the top portion of the delivery vessel or controlling the cooling device disposed at the bottom portion of the delivery vessel or a combination thereof, may be further based on comparison of the sensor data to a profile corresponding to the delivery vessel identifying a predetermined first temperature and first threshold temperature range for at least a top portion of the delivery vessel and a predetermined second temperature and second threshold temperature range for at least a bottom portion of the delivery vessel.

In various examples, the first temperature may be higher than the second temperature. In accordance with various examples of the disclosure, the first temperature may be higher than the sublimation temperature of the chemical and the second temperature may be below a condensation temperature of the chemical. Maintaining the temperature gradient may further comprise holding a top portion of the delivery vessel at a first temperature above a phase change temperature of the chemical and holding a bottom portion of the delivery vessel at a second temperature below a phase change temperature of the chemical and providing a thermal break between the top portion of the delivery vessel and the bottom portion of the delivery vessel.

In accordance with various examples of the disclosure, maintaining the temperature gradient further comprises providing a thermal break between a top portion of the delivery vessel and a bottom portion of the delivery vessel. In some embodiments the thermal break may be disposed in a lower half of the delivery vessel with respect to a longitudinal axis extending from a top surface of the delivery vessel to a bottom surface of the delivery vessel. Alternatively, the thermal break may be disposed in an upper half of the delivery vessel with respect to a longitudinal axis extending from a top surface of the delivery vessel to a bottom surface of the delivery vessel.

In accordance with various examples of the disclosure, maintaining the temperature gradient further comprises dissipating heat through the chemical after solidification of the chemical at a bottom surface of the delivery vessel via thermally conductive cooling members thermally coupled to a base of delivery vessel.

In accordance with various examples of the disclosure, maintaining the temperature gradient further comprises storing, in a controller memory, a first temperature and a first threshold temperature range corresponding to at least a top portion of the delivery vessel, storing, in the controller memory, a second temperature and a second threshold temperature range corresponding to at least a bottom portion of the delivery vessel, wherein the first temperature may be higher than the second temperature, detecting a third temperature within the inner volume of the delivery vessel, and adjusting a heating device or a cooling device responsive to the detecting. The detecting the third temperature may further comprise detecting the third temperature at a top surface of solidified chemical on a bottom surface of the delivery vessel may be above a threshold temperature and adjusting the cooling device to a fourth temperature below the second temperature responsive to the detecting.

In accordance with further examples of the disclosure, a substrate processing system is disclosed comprising a delivery vessel, disposed in a first location on a substrate processing platform, a remote refill vessel in fluid communication with the delivery vessel via a chemical delivery line, the remote refill vessel disposed in a second location remote from the substrate processing platform, a heating device in thermal communication with a top surface of the delivery vessel, a cooling device in thermal communication with a bottom surface of the delivery vessel, a thermal break disposed between the top surface and the bottom surface, a sensor located within an inner volume of the delivery vessel, and a controller coupled to the sensor, the heating device and the cooling device configured to control the heating device and the cooling device responsive to the sensor so as to maintain a temperature gradient within the delivery vessel.

The substrate processing system may further comprise one or more cooling members thermally coupled to a base of the delivery vessel. In some examples, the one or more cooling members comprise rods, fins, or pegs, or a combination thereof.

In accordance with yet further examples of the disclosure, the thermal break may be a vacuum section within a wall of the delivery vessel. The thermal break may be disposed in a top half of the delivery vessel with respect to a longitudinal axis. Alternatively, the thermal break may be disposed in a bottom half of the delivery vessel with respect to a longitudinal axis.

In some examples, the heating device comprises a heater, a heating jacket, a heating block, or a radial heater, or a combination thereof. In additional examples, the cooling device comprises a cooling coil, an integrated cooling channel, a cooling member, a cooling jacket, or a cold plate, or a combination thereof. In accordance with yet further examples of the disclosure, the substrate processing system comprises a plurality of sensors, wherein data from each of the plurality of sensors includes associated location data.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram illustrating an example substrate processing system that includes a delivery vessel disposed on a substrate processing platform;

FIG. 2 is a schematic diagram illustrating an example refill subassembly of substrate processing system depicted in FIG. 1;

FIG. 3 is a schematic diagram illustrating an example delivery vessel, as shown in FIG. 1;

FIG. 4 illustrates an example delivery vessel depicted in FIG. 1, comprising a heating device and cooling device;

FIG. 5 is a schematic diagram illustrating an example bulk refilling process;

FIG. 6A is a schematic diagram illustrating an example delivery vessel depicted in FIG. 1, including heat transfer members;

FIG. 6B is a schematic diagram illustrating a side view of an example delivery vessel depicted in FIG. 1;

FIG. 7 is a schematic diagram illustrating an example bulk refilling process;

FIG. 8 is a schematic diagram illustrating an example delivery vessel depicted in FIG. 1 including heat transfer members coupled to a base;

FIG. 9 is a flowchart illustrating an example solid source refill process;

FIG. 10 is a flowchart illustrating an example solid source refill process;

FIG. 11 is a flowchart illustrating an example solid source refill process;

FIG. 12 is a flowchart illustrating an example solid source refill process; and

FIG. 13 is a flowchart illustrating an example solid source refill process.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

A chemical reactant or solid source delivery system can include a delivery vessel and a heater (e.g., a radiant heat lamp, resistive heater, and/or the like). The delivery vessel includes the source precursor (which may also be referred to as “chemical” or “chemical precursor”), and which can be a solid (e.g., in powder form) or liquid. The heater heats up the delivery vessel to facilitate the vaporization and/or sublimation of the reactant in the vessel. The delivery vessel can have an inlet and an outlet for the flow of a carrier gas through the vessel. The carrier gas may be inert, for example, nitrogen, argon, or helium. Generally, the carrier gas conveys reactant vapor (e.g., evaporated or sublimated chemical reactant) along with it through the vessel outlet and ultimately to a substrate reaction chamber. The vessel typically includes isolation valves for fluidly isolating the contents of the vessel from the vessel exterior. One isolation valve may be provided upstream of the vessel inlet, and another isolation valve may be provided downstream of the vessel outlet. The delivery vessel of some embodiments comprises, consists essentially of, or consists of a sublimator. As such, wherever a “delivery vessel” is mentioned herein, a sublimator (such as a “solid source chemical sublimator”) is also expressly contemplated.

Chemical vapor deposition (CVD) is a known process in the semiconductor industry for forming thin films of materials on substrates such as silicon wafers. In CVD, reactant vapors (including “precursor gases”) of different reactant chemicals are delivered to one or more substrates in a reaction chamber. In many cases, the reaction chamber includes only a single substrate supported on a substrate holder (such as a susceptor), with the substrate and substrate holder being maintained at a desired process temperature. In typical CVD processes, mutually reactive reactant vapors react with one another to form thin films on the substrate, with the growth rate being related to the temperature and the amounts of reactant gases.

In some applications, the reactant gases are stored in a reactant delivery vessel. In such applications, the reactants are often gaseous at standard pressures and temperatures of around 1 atmosphere and room temperature. Examples of such gases include nitrogen, oxygen, hydrogen, and ammonia. However, in some cases, the vapors of source chemicals (“precursors”) that are liquid or solid (e.g., hafnium chloride (HfCl₄), hafnium oxide (HfO₂), zirconium dioxide (ZrO₂), zirconium (IV) chloride (ZrCl₄), aluminum chloride (AlCl₃), tantalum pentafluoride (TaF₅), molybdenum pentafluoride (MoF₅), silicon tetraiodide (SiI₄), molybdenum pentachloride (MoCl₅), molybdenum dichloride dioxide (MoO₂Cl₂), tungsten pentachloride (WCl₅) or the like or combinations thereof) at standard pressure and temperature are used. For some solid substances (referred to herein as “solid source precursors”, “solid chemical reactants”, or “solid reactants”), the vapor pressure at room temperature is so low that they are typically heated and/or maintained at very low pressures to produce a sufficient amount of reactant vapor for the reaction process. Once vaporized (e.g., sublimed or evaporated), keeping the vapor phase reactant at or above the vaporizing temperature through the processing system can prevent undesirable condensation in the valves, filters, conduits, and other components associated with delivering the vapor phase reactants from one location to another, for example from the delivery vessel to the reaction chamber. Vapor phase reactants from such naturally solid or liquid substances are useful for chemical reactions in a variety of other industries.

Atomic layer deposition (ALD) is another known process for forming thin films on substrates. In many applications, ALD uses a solid and/or liquid source chemical as described herein. ALD is a type of vapor deposition wherein a film is built up through self-saturating reactions performed in cycles. The thickness of the film is determined by the number of cycles performed. In an ALD process, gaseous reactants are supplied, alternatingly and/or repeatedly, to the substrate or wafer to form a thin film of material on the wafer. One reactant adsorbs in a self-limiting process on the wafer. A different, subsequently pulsed reactant reacts with the adsorbed material to form a single molecular layer of the desired material. Decomposition may occur through mutual reaction between the adsorbed species and with an appropriately selected reagent, such as in a ligand exchange or a gettering reaction. In some ALD reactions, no more than a molecular monolayer forms per cycle. Thicker films are produced through repeated growth cycles until the target thickness is achieved. In some ALD reactions, mutually reactive reactants are kept separate in the vapor phase with intervening removal processes between substrate exposures to different reactants.

Conventionally, delivery vessels are limited in size due to limited space available on substrate processing platforms. When depleted, delivery vessels are removed and refilled, which can lead to downtime and a loss of wafer production. A remote refill vessel may be coupled to delivery vessel to refill the delivery vessel onboard a substrate processing platform (or “tool”). The remote refill vessels can reduce a need to replace or refill a sublimator. Instead, the remote refill vessels can be used to automatically and/or continuously supply a delivery vessel with chemicals such as source precursor. Thus, remote refill vessels volumes are not subject to size limitations of vessels disposed on the substrate processing platform. In some examples, a remote refill vessel may be disposed in a location that is spaced apart from the tool. For example, a remote refill vessel may be located in another room from the substrate processing platform, across a cleanroom from the substrate processing platform, adjacent to the substrate processing platform or in a sub-fab. For the purposes of this disclosure a “sub-fab” is an area underneath a substrate processing platform. In some examples, it may be built into the floor of a cleanroom, in a building level lower than the level on which the substrate processing platform is disposed or may comprise a lower portion of substrate processing platform. Multiple remote refill vessels may be included for filling the delivery vessel with source precursor as described herein.

Remote refill vessels and/or delivery vessels may be supplied with gas lines extending from the inlet and outlet, isolation valves on the lines, and fittings on the valves, the fittings being configured to connect to the gas flow lines of the remaining substrate processing platform. It is desirable to provide a number of additional heaters for heating the various valves and gas flow lines between the reactant delivery vessel and the reaction chamber, to prevent the reactant liquid or vapor from solidifying or condensing and depositing on such components. Accordingly, the gas and/or liquid conveying components between the remote refill vessel, delivery vessel and the reaction chambers may be maintained at a temperature above the vaporization/condensation/sublimation temperature of the reactant.

Additionally, in order to efficiently refill a delivery vessel it is advantageous to refill the vessel by deposition or condensation in a controlled way. To control deposition, temperature of the depositing chemical precursor may be controlled to reduce or prevent condensation or clogging of the input (or output) lines which attach to the delivery vessel lid that allow fluid communication to the reactor and “outside” world. Furthermore, bottom-up filling or filling from the bottom and interior sidewalls in of the delivery vessel may enable near filling of the on-board delivery vessel.

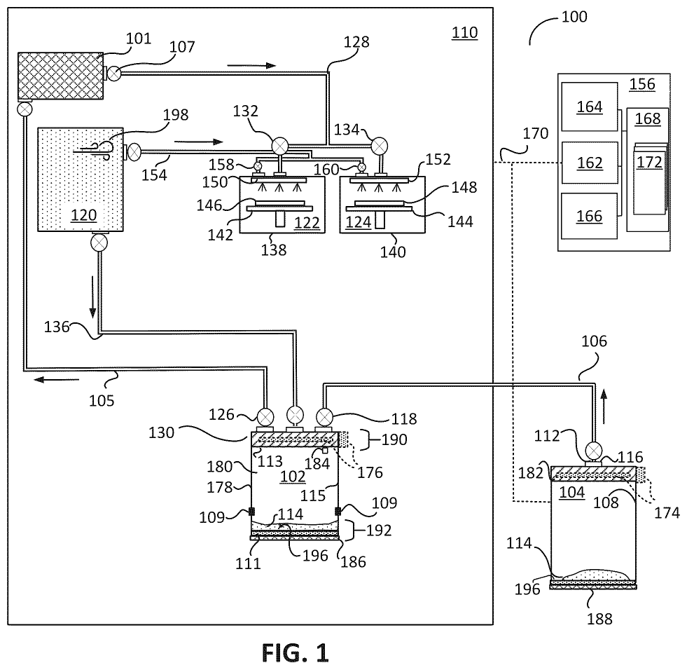

FIG. 1 is a schematic illustrating an example substrate processing system 100 that includes a delivery vessel 102 disposed on substrate processing platform 110. Substrate processing platform 110 includes one or more reactors 138 and 140 including respective reaction chambers 122 and 124. Reactors 138 and 140 include respective susceptors 142 and 144 to hold respective substrates 146 and 148 during processing. Substrate processing platform 110 includes gas distribution systems 150 and 152 to distribute one or more reactants to respective surfaces of substrates 146 and 148. Substrate processing platform 110 may include a vacuum source (not shown) for controlling vacuum pressure in one or more of reaction chambers 122 and 124. A reactant source may feed a gas-phase reactant, generated from a solid precursor source delivery vessel 102 into gas-phase reactors. Reaction chambers 138 and/or 140 may be gas-phase reactors. The solid source delivery vessel 102 may contain chemical 114 comprising a chemical reactant such as source chemicals or precursor including but not limited to HfCl₄, HfO₂, ZrO₂, ZrCl₄, AlCl₃, TaF₅, MoF₅, SiI₄, MoCl₅, MoO₂Cl₂, WCl₅ or the like or combinations thereof. Chemical 114 may be solid under standard conditions (i.e., room temperature and atmospheric pressure). A carrier gas source 120 may be coupled to delivery vessel 102 via chemical delivery line 136 and may hold a carrier gas. Carrier gas source 120 may be fluidly coupled to reaction chambers 122 and 124 via chemical delivery line 154 and valves 158 and 160. When introduced into delivery vessel 102, the carrier gas 198 helps transport vaporized and/or sublimed reactants such as chemical 114 through vessel outlet valve 126 via chemical delivery line 105 to an accumulator 101. From accumulator 101, chemical 114 may exit valve 107 and be carried through chemical delivery line 128 to reaction chambers 122 and/or 124 for substrate processing. Accumulator 101 may regulate the flow of chemical 114 gas and may maintain a consistent pressure and flow rate throughout processing of the substrate. Chemical delivery line 128 may comprise valves 132 and 134 for controlling fluid communication of chemical 114 and/or carrier gas from delivery vessel 102 to respective reaction chambers 122 and 124. Inlet and outlet valves onboard substrate processing platform 110 may be controlled by one or more controllers (e.g., controller 156).

In an example, delivery vessel 102 may be coupled to a remote refill vessel 104 via a chemical delivery line 106. Remote refill vessel 104 may be located distant laterally, above or below delivery vessel 102 and/or substrate processing platform 110, for example in a sub-fab located beneath substrate processing platform 110.

Remote refill vessel 104 may contain refill chemical 114. Remote refill vessel 104 may be a bulk refill container that may have a larger chemical capacity within housing 108 than delivery vessel 102 as it may not be restrained by dimension restrictions associated with substrate processing platform 110. For example, remote refill vessel 104 may have at least 1.5×, 2×, 3×, 4×, 5×, 10×, or 20× the capacity of delivery vessel 102. Other capacities are possible and claimed subject matter is not limited in this regard.

Chemical delivery line 106 may extend between outlet valve 116 of remote refill vessel 104 and inlet valve 118 of delivery vessel 102. Inlet valve 118 may be disposed in lid 130 of delivery vessel 102. Outlet valve 116 may be disposed in lid 182 of remote refill vessel 104. Outlet valve 116 and inlet valve 118 may control fluid communication of chemical 114 from remote refill vessel 104 to delivery vessel 102.

Remote refill vessel 104 may be equipped to vaporize (e.g., sublimate, evaporate) chemical 114 and may subsequently pass vaporized or sublimated chemical 114 to delivery vessel 102 via chemical delivery line 106. In an example, remote refill vessel 104 may be proximate a heating device 174. Heating device 174 may be in thermal communication with lid 182 and/or housing 108 and may be disposed exterior to remote refill vessel 104 or within an interior portion of lid 182 and/or housing 108. Housing 108 may be made of a thermally conductive material (e.g., stainless steel) and may be configured to transfer heat from heating device 174 to a lid 182 and/or an interior volume of remote refill vessel 104. Heating device 174 may be configured to heat chemical 114 to a temperature sufficient to change the phase of chemical 114, such as to vaporize and/or sublimate chemical 114 in order to transfer chemical 114 via chemical delivery line 106 to delivery vessel 102. Heating device 174 may comprise any of a variety of heating devices such as heaters, heating jackets, heating blocks, and/or radial heaters, or the like known to those of skill in the art and claimed subject matter is not limited in this regard.

Remote refill vessel 104 may be configured to store chemical 114 between refill operations. A cooling device 188 may be coupled to a bottom portion of remote refill vessel 104. Cooling device 188 may cool bottom surface 196 so as to maintain chemical 114 in solid form prior to sublimation. Cooling device 188 may comprise a chill plate, cooling coil, a cooling jacket, cooling fans, a Peltier cooler, cooling members, or integrated coolant channels circulating coolant or the like or any combination thereof.

Remote refill vessel 104 may be configured to operate at a selected temperature. For example, the operating temperature may be determined based on a desired subliming rate of the chemical precursor/reactant. In some examples, the operating temperature is in the range of about 10° C. to about 500° C. or a range of about 50° C. to about 400° C. or a range of about 75° C. to about 300° C. or a range of about 100° C. to about 250° C. The selected operating temperature may depend, of course, upon the chemical to be vaporized or sublimed. Other temperature ranges are possible and claimed subject matter is not limited in this regard.

Delivery vessel 102 may receive chemical 114 in gas phase via chemical delivery line 106 from remote refill vessel 104. Chemical delivery line 106 may be disposed at the top portion 190 of delivery vessel 102, for example, in lid 130. In an example, lid 130 and inlet valve 118 may be configured to maintain a temperature above the vaporization temperature of chemical 114 as it passes into delivery vessel 102 so as to prevent chemical 114 from condensing in delivery vessel components such as lid 130, valves 184 and/or 118, or chemical delivery line 106, or the like or any combination thereof.

Delivery vessel 102 may be thermally coupled to one or more heating devices 176 for heating chemical 114 and maintaining chemical 114 in vapor phase at top portion 190 of delivery vessel 102. Heating devices 176 may comprise, a heater, heating jacket, heating block, heating fins, and/or radial heater, or the like or a combination thereof. Heating devices 176 may be disposed at top portion 190 of delivery vessel 102, for example, within lid 130 and/or outside of delivery vessel 102. Such heating devices 176 serve to control or adjust the temperature of chemical 114 during refilling operations, material processing operations and storage of chemical 114.

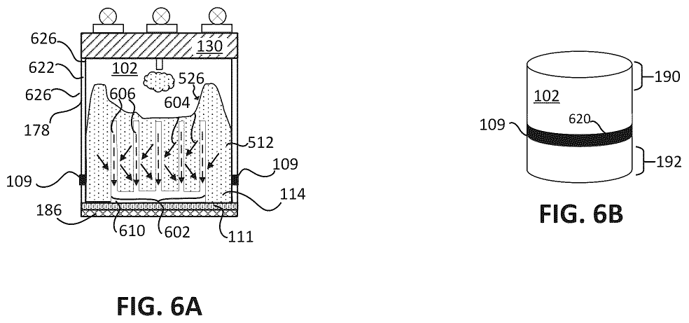

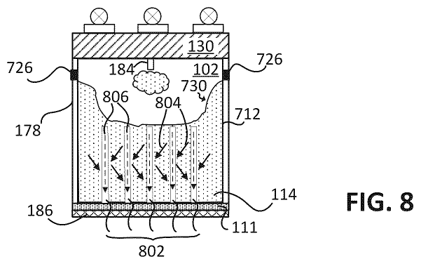

A bottom portion 192 of delivery vessel 102 may be thermally coupled to one or more cooling devices 186 for cooling chemical 114 at bottom portion 192 of delivery vessel 102. Cooling devices 186 may comprise, a chill plate, cooling coils, variable pitch cooling coils, a cooling jacket, cooling members (e.g., cooling rods, and/or cooling fins (see FIGS. 6 and 8), cooling fans, a Peltier cooler or integrated coolant channels circulating coolant or the like or any combination thereof.

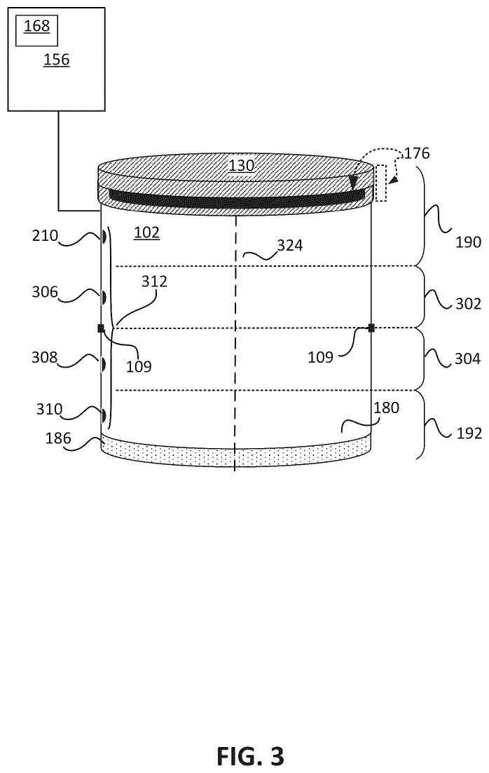

As will be discussed in more detail, such heating devices 176 and cooling devices 186 provide a temperature gradient (see element 324 in FIG. 3) within delivery vessel 102.

In an example, interior sidewall 178 and/or lid 130 may be configured to transfer heat from heating device 176 to chemical 114 before it enters delivery vessel 102 to maintain a temperature above a condensation point of chemical 114. Such applied heat and/or pressure may maintain chemical 114 in vapor phase. As chemical 114 cools it may condense at bottom surface 196 and/or interior sidewalls 178 below thermal break 109.

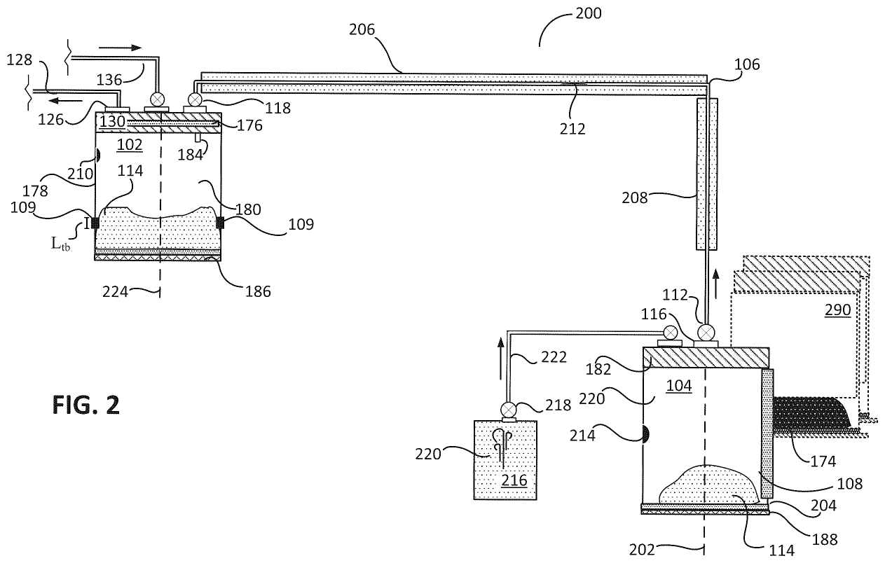

Delivery vessel 102 bottom portion 192 temperature may be cooled by a cooling device 186 (e.g., a cold plate) to a lower temperature than incoming chemical delivery line 106, interior sidewalls 178 above thermal break 109 (discussed below in more detail) or lid 130 of delivery vessel 102. This provides a temperature gradient along longitudinal axis 224 (see FIG. 2) where the highest temperature in the system may be at the top portion 190 of delivery vessel 102 and the lowest temperature in the system may be at the base 111. Chemical 114 may solidify upon contact with bottom interior surface 196 of base 111 of delivery vessel 102. During refill, chemical 114 will form a solid at the bottom of delivery vessel 102 and may be stored there until a material processing operation. Cooling device 186 may maintain a temperature at bottom portion 192 of delivery vessel 102 sufficient to maintain chemical 114 in solid phase.

In delivery vessel 102, a thermal break 109 may insulate a top portion 190 of delivery vessel 102 from a bottom portion 192. This may help keep the top portion 190 of delivery vessel 102 at a higher temperature compared to bottom portion 192. Thermal break 109 may reinforce a temperature gradient extending from the top portion 190 to bottom portion 192 of delivery vessel 102. This may facilitate deposition of chemical 114 on interior sidewalls 115 below thermal break 109 and a bottom surface 196 of delivery vessel 102.

In an example, thermal break 109 may be disposed circumferentially about the delivery vessel 102 between top portion 190 and bottom portion 192. Thermal break 109 may be formed by a variety of methods. For example, thermal break 109 may comprise a ring of insulating material embedded in interior sidewalls 178. It may be embedded by any of a variety of methods known to those of skill in the art such as by welding, brazing, bonding, gas tight fastening, or the like or a combination thereof.

In an example, thermal break 109 may consist of an insulating layer disposed within vessel interior sidewalls 178. Sidewalls may be double walled having a hollow portion or space between inner and outer walls. Thermal break 109 may be a section of the double-wall that filled with insulating material or a vacuum. The insulating material may be a variety of materials such as ceramic fiber, high-temperature insulation wool and/or a foam insulation (e.g., polystyrene, polyurethane, or polyisocyanurate). The length Lib of thermal break 109 in the longitudinal axis of delivery vessel 102 may vary depending on a variety of factors such as the temperature range desired within delivery vessel 102, chemical properties of chemical 114 to be stored, materials used in the delivery vessel 102 and insulating layer within thermal break 109 and/or other like factors.

Thermal break 109 may prevent heat from dissipating from the top portion 190 of delivery vessel 102 so as to better maintain a temperature above a condensation temperature of chemical 114 at the top portion 190. This may reduce or prevent condensation of chemical 114 and thus clogging of components such as chemical delivery line 106, valves 118, 126 and 184 and the like, or combinations thereof.

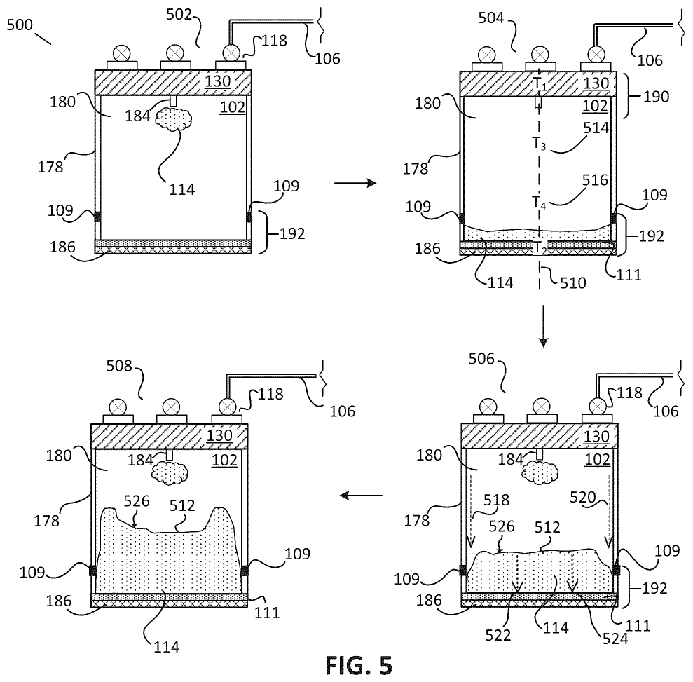

During a refilling operation (shown in FIG. 5-FIG. 8), delivery vessel 102 may be configured to operate with a temperature gradient within the interior volume 180. For example, the operating temperature proximate top portion 190 may be determined based on a desired condensation rate of chemical 114. In some examples, the operating temperature is in the range of about 10° C. to about 500° C. or a range of about 50° C. to about 400° C. or a range of about 75° C. to about 300° C. or a range of about 100° C. to about 250° C. The selected operating temperature may depend upon the vaporization temperature of chemical 114. Likewise, delivery vessel 102 base 111 may be maintained at a lower temperature than the top portion 190 to solidify chemical 114 on base 111 and to maintain the temperature gradient within delivery vessel 102. The selected operating base temperature again may depend upon the chemical to be solidified. Additionally, to prevent gaseous particles from solidifying in unwanted areas on the interior of delivery vessel 102, bottom portion 192 may be set to a temperature that is at least cooler than top portion 190. In an example, base 111 is the coolest location in the interior volume 180 of delivery vessel 102. Thus, the operating temperature at base 111 may be well below a condensation point of chemical 114.

In an example, the temperature gradient may extend between base 111 and lid 130. In an example, bottom portion 192 may be maintained at or below a first threshold temperature, while top portion 190 may be maintained at or above a second threshold temperature that is greater than the first threshold temperature. For example, the base 111 and lid 130 may be maintained at a difference in temperature (e.g., a difference between the first threshold temperature and the second threshold temperature). In an example, the difference in temperature between the base 111 and lid 130 may be at least about 1° C., about 5° C., about 10° C., about 20° C., about 30° C., about 40° C., about 50° C., about 60° C., about 70° C., about 80° C., or about 160° C., or any value therebetween, or fall within any range having endpoints therein. Other temperature differences are possible and claimed subject matter is not limited in this regard.

In an example, the temperature gradient can be disposed across an axial distance along longitudinal axis 224 (see FIG. 2) of about 1 inch, about 3 inches, about 6 inches, about 9 inches, about 12 inches, about 15 inches, about 18 inches, about 21 inches, about 24 inches, about 27 inches, about 30 inches, about 32 inches, about 34 inches, about 36 inches, about 64 inches, or about 128 inches, or any value therebetween, or fall within any range having endpoints therein. The gradient may be stepwise or linear. Other gradient dimensions are possible and claimed subject matter is not limited in this regard.

In an example, during a material processing operation, heating device 176 may be configured to heat chemical 114 to a temperature sufficient to change the phase of chemical 114, such as to vaporize and/or sublimate chemical 114. Once vaporized or sublimed, chemical 114 may be transported as described previously to reaction chambers 122 and/or 124 for substrate processing. Prior to vaporization and/or sublimation, chemical 114 may be stored as a solid in delivery vessel 102.

During material processing, delivery vessel 102 may be configured to operate at a selected temperature based on a desired subliming rate of chemical 114 precursor/reactants. In some examples, the operating temperature is in the range of about 10° C. to about 500° C. or a range of about 50° C. to about 400° C. or a range of about 75° C. to about 300° C. or a range of about 100° C. to about 250° C. Other temperature ranges are possible and claimed subject matter is not limited in this regard.

Once depleted of chemical 114, delivery vessel 102 may be refilled from remote refill vessel 104. It may not be necessary to completely deplete delivery vessel 102 of chemical 114 prior to refilling from remote refill vessel 104.

In the illustrated example controller 156 includes a device interface 162, a processor 164, a user interface 166, and a memory 168. The device interface 162 connects the processor 164 to the wired or wireless link 170. The processor 164 may be operably connected to the user interface 166 (e.g., to receive user input and/or provide user output therethrough) and may be disposed in communication with the memory 168. The memory 168 includes a non-transitory machine-readable medium having a plurality of program modules 172 recorded thereon containing instructions that, when read by the processor 164, cause the processor 164 to execute certain operations. Among the operations are operations of a material layer deposition method and methods for refilling a delivery vessel 102 (shown in FIGS. 5-6A and 7-13), as will be described. As will be appreciated by those of skill in the art in view of the present disclosure, the controller 156 may have a different arrangement in other examples and remain within the scope of the present disclosure.

FIG. 2 is a schematic diagram illustrating an example refill subassembly 200 of substrate processing system 100 depicted in FIG. 1. Refill subassembly 200 includes delivery vessel 102 coupled to remote refill vessel 104 via chemical delivery line 106. Remote refill vessel 104 may be configured to maintain a temperature gradient along a longitudinal axis 202 to store chemical 114 (e.g., precursor) in a solid state prior to being sublimed or vaporized. Base 204 of the remote refill vessel 104 may be at a relatively low temperature (e.g., to maintain the precursor as a solid). Lid 182 may reach relatively high temperatures to facilitate transportation to delivery vessel 102. Such temperatures are sufficient to at least cause chemical 114 to enter the vapor phase and minimize condensation in downstream flow path components such as: chemical delivery line 106, lid 182, outlet valve 116, and inlet valve 118.

In some examples, a carrier gas source 216 may be coupled to remote refill vessel 104 via chemical delivery line 222 and may supply carrier gas 220 to remote refill vessel 104. Valve 218 may control the flow of carrier gas 220. Carrier gas 220 may assist transport of the sublimated chemical 114 from the remote refill vessel 104 to delivery vessel 102.

In an example, heaters 206 and 208 may be coupled to chemical delivery line 106 to maintain a “transport temperature” which may be a vaporization temperature to prevent condensation during transport. Such vaporization temperatures may be above a phase change temperature (e.g., a sublimation temperature) of chemical 114. Heaters 206 and 208 may comprise heater jackets or other heating devices known to those of skill in the art and claimed subject matter is not limited in this regard. Heaters 206 and 208 may be wrapped around, coiled, envelop, or otherwise be disposed in close proximity to chemical delivery line 106. Chemical delivery line 106 may have very few angles or corners to discourage condensation. Valves, connection points and/or other interruptions in the chemical delivery line 106 may be minimized to the extent possible to offset a higher risk of condensation in chemical delivery line 106 due to the disposition of remote refill vessel 104 distant from (i.e., spaced apart) from substrate processing platform 110 (see FIG. 1).

In an example, one or more back-up remote refill vessels 290 may be co-located with remote refill vessel 104 to reduce downtime required to replace remote refill vessel 104 when depleted. When remote refill vessel 104 needs to be replaced, back-up remote refill vessels 290 may be quickly coupled to delivery vessel 102 via chemical delivery line 106 (or via a different chemical delivery line) to avoid downtime waiting for remote refill vessel 104 to be removed and replaced. Alternatively, back-up remote refill vessels 290 may be coupled to remote refill vessel 104 to refill vessel 104 at other opportune idle times, such as between refill operations or upstream events requiring downtime on the substrate processing platform 110.

In an example, the refilling process may be controlled manually and/or refill operations may be partially or fully automated using a variety of sensors for automated feedback control by a controller 156. For example, sensor 210 may be disposed adjacent to or within an interior volume 180 of delivery vessel 102, sensor 212 may be disposed within or adjacent to chemical delivery line 106 and sensor 214 may be disposed adjacent to or within an interior volume 220 of remote refill vessel 104. Sensors 210, 212, and 214 may monitor a variety of physical phenomenon such as, for example, acoustics, vibration, chemicals, moisture, flow, light, pressure, force, density, temperature and/or presence, or the like or any combinations thereof. Sensors 210, 212, and/or 214 may, for example, monitor a temperature gradient in delivery vessel 102 and/or monitor a temperature of the chemical 114 disposed in at least one of the chemical delivery lines 106, delivery vessel 102 or the remote refill vessel 104, or a combination thereof. Sensors 210, 212, and/or 214 may alternatively or additionally monitor a temperature of or within chemical delivery line 106, delivery vessel 102 and/or remote refill vessel 104, or a combination thereof. Sensors 210, 212, and/or 214 may generate sensor data based on the monitoring and send the sensor data to controller 156 (see, FIG. 1) to adjust the monitored devices to change a monitored parameter (e.g., temperature). For example, controller 156 may adjust one or more of heating devices 174, 176, 206 and/or 208 and/or cooling devices 186 and 188 or a combination thereof based on the sensor data. In some embodiments, the electronics and/or computer elements for use in controlling one or more of reaction chamber 122, reaction chamber 124, delivery vessel 102 and/or remote refill vessel 104 can be found elsewhere in the system. For example, central controllers may control both apparatus of the one or more chambers themselves as well as control the valves that connect to the various vessels and any associated heating devices. One or more valves may be used to control the flow of gas throughout substrate processing system 100.

FIG. 3 is a schematic diagram illustrating an example delivery vessel 102 and lid 130 coupled to top portion of delivery vessel 102, as shown in FIG. 1.

Temperature gradient 324 may comprise a first temperature in top portion 190, a second temperature in upper middle portion 302, a third temperature in lower middle portion 304 and a fourth temperature in bottom portion 192. An ideal temperature gradient for a delivery vessel 102 refill operation with chemical 114 would comprise having a temperature above thermal break 109 higher than the condensation temperature of chemical 114 and lower than the condensation temperature of chemical 114 below the thermal break 109. For example, the first temperature and the second temperatures would be the same, above the condensation temperature of chemical 114 and higher than the third temperature and the fourth temperatures. In such an ideal system the third temperature and the fourth temperature would be the same, below the condensation temperature and lower than first and second temperatures.

However, in a real system the temperature gradient 324 may gradually cool from a highest temperature in the top portion 190 to the lowest temperature in the bottom portion 192. The first temperature may be greater than the second temperature. Both the first and second temperatures may be above the condensation temperature of chemical 114 to protect delivery vessel 102 components. The third temperature may be greater than the fourth temperature, both may be below the condensation temperature of chemical 114 and both may be lower than the first and second temperatures.

Temperature gradient 324 may be maintained via a feedback mechanism including controller 156. Sensor array 312 may comprise one or more sensors 210, 306, 308, and/or 310 disposed within interior volume 180 of delivery vessel 102. Sensors 210, 306, 308, and/or 310 may monitor a variety of physical phenomenon such as, for example, acoustics, vibration, chemicals, moisture, flow, light, pressure, force, density, temperature and/or presence, or the like or any combinations thereof. Sensors 210, 306, 308, and/or 310 may be positioned along temperature gradient 324 at selected locations of delivery vessel 102 so as to correlate temperature data (or other data) and position along temperature gradient 324. For example, sensor 210 may be disposed within top portion 190, sensor 306 may be disposed within upper middle portion 302, sensor 308 may be disposed within lower middle portion 304, and sensor 310 may be disposed within bottom portion 192. At least one sensor of sensors 210, 306, 308, and/or 310 may monitor a physical phenomenon (e.g., take temperature readings) and/or communicate sensor data (including, for example, data related to physical phenomenon measured/monitored, sensor identification, location data, or the like or a combination thereof to controller 156. In an example, location data may be stored in memory 168 in a table correlated to a sensor identification associated with a sensor's location within volume 180 of delivery vessel 102.

In an example, controller 156 may control heating device 176 and/or cooling device 186 based on data from sensors 210, 306, 308, and/or 310 to maintain temperature gradient 324. Temperature gradient 324 may be based on a temperature programmed temporal profile. Temperature gradient 324 may be maintained in a variety of other ways and based on various sensor data, and/or stored temporal profile and temperature parameters and claimed subject matter is not limited in this regard.

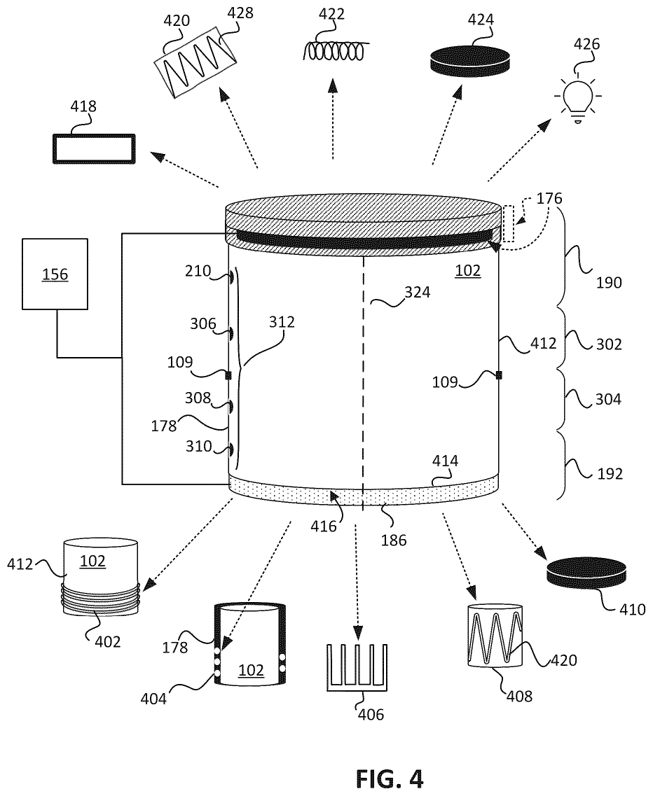

FIG. 4 illustrates an example delivery vessel 102 comprising heating device 176 and cooling device 186. In an example, temperature gradient 324 extends from a first temperature above a condensation temperature of chemical 114 at top portion 190 to a second temperature below a condensation temperature of chemical 114 near the bottom portion 192 of delivery vessel 102. Chemical 114 may be transported to delivery vessel 102 from a remote refill vessel 104 in vapor phase. It may be desirable that chemical 114 first condense on the coldest location in delivery vessel 102 at bottom surface 414 which may be cooled by cooling device 186. This first condensation portion may act as a nucleation site for further solidification of chemical 114 entering delivery vessel 102. Lid 130 may be maintained at a higher temperature to prevent chemical 114 from condensing in components such as inlet valve 118, outlet valve 126 and/or chemical delivery line 106 (see FIG. 1). Thus, it is desirable to maintain temperature gradient 324 to encourage solidification of chemical 114 on cooled inner surface 414 and to prevent chemical 114 from solidifying in and around lid 130. Temperature gradient 324 may abruptly or gradually change from a highest temperature at top portion 190 to a lowest temperature at bottom portion 192 of delivery vessel 102 depending on the efficacy and placement of thermal break 109. Heating device 176 and cooling device 186 may be coupled to controller 156 which may be configured to control heating device 176 and cooling device 186 responsive to sensors 210, 306, 308, and/or 310, of sensor array 312 to maintain temperature gradient 324.

In an example, cooling device 186 may comprise any of a variety of cooling mechanisms such as, for example, cooling coils 402, integrated cooling channels 404, cooling members 406, cooling jacket 408, cold plate 410, and/or or the like or combinations thereof. Controller 156 may control various functions (e.g., device temperature, coolant temperature, coolant flow) of cooling device 186 to maintain temperature gradient 324.

In an example, cooling coils 402 may be disposed on a portion of an outer surface 412 near bottom portion 192 or at any level of delivery vessel 102. Cooling coils 402 may assist in maintaining temperature gradient 324 by keeping bottom portion 192 cooled to below a threshold temperature (e.g., a condensation temperature of chemical 114). Cooling coils 402 may be hollow to allow a coolant to flow therethrough. The coolant may be any of a variety of coolants known to those of skill in the art such as water, deionized water, glycol/water solutions, and dielectric fluid, or the like or a combination thereof. Cooling coils 402 may be formed from a variety of thermally conductive materials including but not limited to stainless steel, aluminum, copper, or the like or combinations thereof.

In an example, integrated cooling channels 404 may be formed (e.g., machined, etched and/or 3D printed) into interior sidewalls 178 of delivery vessel 102 at any level. Integrated cooling channels 404 may assist in maintaining temperature gradient 324 by keeping bottom portion 192 cooled to below a threshold temperature. Integrated cooling channels 404 may be hollow to allow a coolant to flow therethrough. The coolant may be any of a variety of coolants known to those of skill in the art such as water, deionized water, glycol/water solutions, and dielectric fluid, or the like or a combination thereof. Integrated cooling channels 404 may further comprise conduit disposed within cooling channels 404 formed from thermally conductive material.

In an example, cooling members 406 may be coupled to bottom surface 414. As discussed with respect to FIG. 2, cooling members 406 may assist in maintaining temperature gradient 324 by dissipating heat through solid chemical 114 formed during a refill operation on surface 414. Such cooling through the solid mass may facilitate cooling at a top surface of solid chemical 114 to below a threshold temperature. Cooling members 406 may be formed from thermally conductive material such as stainless steel, aluminum, copper, or the like or combinations thereof.

In an example, cooling jacket 408 may be disposed on a portion of outer surface 412 near bottom portion 192 or at any level of delivery vessel 102. Cooling jacket 408 may be a casing comprising integrated cooling conduit 420. Cooling jacket 408 may assist in maintaining temperature gradient 324 by keeping bottom portion 192 cooled to below a threshold temperature. Cooling conduit 420 may be hollow to allow a coolant to flow therethrough. The coolant may be any of a variety of coolants known to those of skill in the art such as water, deionized water, glycol/water solutions, and dielectric fluid, or the like or a combination thereof.

In an example, cold plate 410 may be disposed on a bottom surface 416 of delivery vessel 102. Cold plate 410 may be a flat metal plate made of a material having high thermal conductivity, such as aluminum. Cold plate 410 may assist in maintaining temperature gradient 324 by keeping bottom portion 192 cooled to below a threshold temperature by dissipating heat from bottom surface 416. Cold plate 410 may have integrated cooling channels and/or embedded cooling conduit allowing a coolant to flow therethrough to draw additional heat away from bottom surface 414.

In an example, heating device 176 may comprise any of a variety of heating mechanisms such as, for example, heating block 418, heating jacket 420, resistive heater 422, hot plate 424, heat lamp 426, and/or or the like or combinations thereof. Controller 156 may control various functions (e.g., device temperature, brightness, temperature ramping) of heating device 176 to maintain temperature gradient 324.

In an example, heating jacket 420 may be thermally coupled to and disposed on a portion of an outer surface 412 near top portion 190 of delivery vessel 102. Heating jacket 420 may assist in maintaining temperature gradient 324 by heating components near top portion 190 such as lid 130, valves 118, 184, and/or 126, chemical delivery line 106, (see FIG. 1) or the like or combinations thereof above a threshold temperature (e.g., a condensation temperature of chemical 114). Heating jacket 420 may comprise a casing having integrated heating elements 428. The integrated heating elements 428 may be conduit through which a heated fluid may flow or may be resistive heating devices.

In an example, resistive heater 422 may be thermally coupled to delivery vessel 102 at top portion 190 and/or within lid 130. Resistive heater 422 may assist in maintaining temperature gradient 324 by heating components near top portion 190 such as lid 130, valves 118, 184, and/or 126, chemical delivery line 106, or the like or combinations thereof above a threshold temperature.

In an example, hot plate 424 may be thermally coupled to delivery vessel 102 at top portion 190 and/or within lid 130. Hot plate 424 may assist in maintaining temperature gradient 324 by heating components near top portion 190 such as lid 130, valves 118, 184, and/or 126, chemical delivery line 106, or the like or combinations thereof above a threshold temperature.

In an example, heat lamp 426 may be thermally coupled to delivery vessel 102 at top portion 190 and/or within lid 130. Heat lamp 426 may assist in maintaining temperature gradient 324 by heating components near top portion 190 such as lid 130, valves 118, 184, and/or 126, chemical delivery line 106, or the like or combinations thereof above a threshold temperature.

FIG. 5 is a schematic diagram illustrating an example bulk refilling process 500. In an example, delivery vessel 102 may be heated by any of a variety of heating devices in top portion 190 (as described in detail above with reference to FIGS. 1-4) and may be actively cooled by any of a variety of cooling devices (as described in detail above with reference to FIG. 1-4). A thermal break 109 may be provided within the delivery vessel 102 to thermally isolate the actively cooled bottom portion 192 from the heated top portion 190. Such thermal isolation may serve to facilitate condensation of chemical 114 in the actively cooled area of delivery vessel 102 after chemical 114 exits heated components (e.g., lid 130, valve 184 and/or chemical line 106) in a gaseous form in top portion 190.

Bulk refilling process 500 starts as illustrated schematically in stage 502, with chemical 114 entering interior volume 180 of delivery vessel 102 in gaseous form. Chemical 114 flows into interior volume 180 through heated lid 130 via heated chemical line 106. As chemical 114 continues to flow into delivery vessel 102, chemical 114 begins to condense and deposit at bottom portion 192. At stage 504, chemical 114 begins to accumulate at base 111 within interior volume 180 of delivery vessel 102. The driving force is vapor pressure delta between 150° C. pure component v.p. and 130° C. v.p. In an example, there may be no external pumping to drive flow of chemical 114. Rather, the driving force may be a pressure gradient to drive gas transport from remote refill vessel 104 to delivery vessel 102 created by condensation of chemical 114 within delivery vessel 102. The pressure gradient created by the phase change of chemical 114 from gas to solid can drive the gas flow from refill vessel 104 to delivery vessel 102.

Thermal break 109 is disposed near bottom portion 192 of delivery vessel 102. In an example, thermal break 109 may consist of an insulating layer disposed within interior sidewalls 178. Sidewalls may be double walled having a hollow portion 622 (e.g., space) between inner wall 624 and outer wall 626. Thermal break 109 may be a section of the double-wall that is filled with insulating material or a vacuum.

Example temperatures provided herein are for illustrative purposes only and are not intended to limit claimed subject matter. Representative temperatures are for a chemical 114 whose condensation temperature is about 150° C.

In an example, a temperature gradient 510 extends along the length of delivery vessel 102 in the longitudinal direction from a higher temperature T1 (e.g., about 170° C.) at top portion 190 to a lower temperature, T2, (e.g., about 130° C.) at bottom portion 192.

In an example system, thermal break 109 may not completely insulate bottom portion 192, thus the temperature may gradually decrease from top portion 190 longitudinally toward bottom portion 192. For example, temperature T3 may be between temperature T1 and temperature T2 (e.g., about 160° C.) and temperature T4 may be between temperature T3 and temperature T2 (e.g., about 150° C.). However, the temperatures T3 and T4 may still be above the phase change temperature of chemical 114. This may reduce clogging in the lid 130, valve 184 and/or chemical line 106. Moreover, it may reduce condensation on interior sidewalls 178 in top portion 190. Heat dissipates from heated top portion 190 of delivery vessel 102 to cooled bottom portion 192. Chemical 114 may cool to its phase change temperature upon contact with surfaces at or below the phase change temperature and/or when ambient atmosphere is at or below the phase change temperature causing it to condense.

At stage 506, as chemical 114 continues to condense within delivery vessel 102, solid chemical 114 may build up higher in the middle portion forming a vertical column 512 rather than filling up evenly across surface 526 due to the distribution of temperature within delivery vessel 102. Interior sidewalls 178 may be warmer than bottom portion 192 due to dissipation of heat through delivery vessel 102 from heated components in top portion 190. Thus, the temperature of interior sidewalls 178 at or above thermal break 109 may be above the phase change temperature of chemical 114 and thus chemical 114 may not condense on interior sidewalls 178 at or above thermal break 109. Dashed arrows 518 and 520 point in the direction of dissipation of heat through sidewalls 178.

Heat also dissipates through chemical 114 from the surface 526 to base 111. Dotted arrows 522 and 524 point in the direction of dissipation of heat through solidified chemical 114. Heat dissipation through chemical 114 may be slower than heat dissipation through interior sidewalls 178. As the condensed thickness grows, the heat transfer through chemical 114 will become increasingly difficult and the heat of sublimation cannot be rejected readily. At this point, temperatures within vertical column 512 and/or at surface 526 may reach a temperature of that of the interior sidewalls 178 and not the colder base 111 causing condensation of chemical 114 to slow or cease and vertical column 512 to stop growing. The height of vertical column 512 at which condensation may cease depends on the thermal conductivity of chemical 114.

Moving to stage 508, in an example, reducing the base 111 temperature may reduce the temperature of chemical 114 surface 526 and reinitiate (or further enable) condensation of chemical 114 in vertical column 512. Continuing with the above example temperatures, surface 526 may reach about 150° C. when condensation ceases. Lowering base 111 temperature, for example, from about 130° C. to about 110° C. may cool surface 526 (and interior sidewalls 178) and may re-initiate condensation allowing vertical column 512 to reach a new height. As the temperature of base 111 is lowered the resultant cooling may extend through delivery vessel 102 interior sidewalls 178 into lid 130, valves 184 and 118 and/or chemical delivery line 106. Clogging of these and other components could occur. In some examples, since the growing solid is increasing in heat capacity, it may not be necessary for the base temperature to be lowered by heat flux increase in order to maintain colder temperature.

FIG. 6A illustrates an example delivery vessel 102 including heat transfer members 602 coupled to base 111. Thermal conductivity of powder chemical 114 may be lower than material the delivery vessel 102 is made of such as stainless steel. In an example, one or more heat transfer members 602 may be coupled to base 111 to improve thermal conductivity through chemical 114. Heat transfer members 602 may provide shorter paths for heat diffusion through powder chemical 114 to cool surface 526. Heat transfer members 602 may be connected about a common member base 610 configured to couple to base 111. Alternatively, heat transfer members 602 may be individual members each connected to base 111 (see also FIG. 8). Heat transfer members 602 may comprise fins, round rods, polygonal pegs, or the like or any of a variety of heat transfer devices known to those of skill in the art, or combinations thereof. Contrasting arrows 604 indicate the direction of heat transfer from chemical 114 to heat transfer members 602. Arrows 606 indicate the direction of heat transfer longitudinally along heat transfer members 602 from the top of heat transfer members 602 to base 111.

FIG. 6B illustrates a side view of an example delivery vessel 102. Thermal break 109 may be disposed circumferentially forming an annular ring 620 about the delivery vessel 102 between top portion 190 and bottom portion 192.

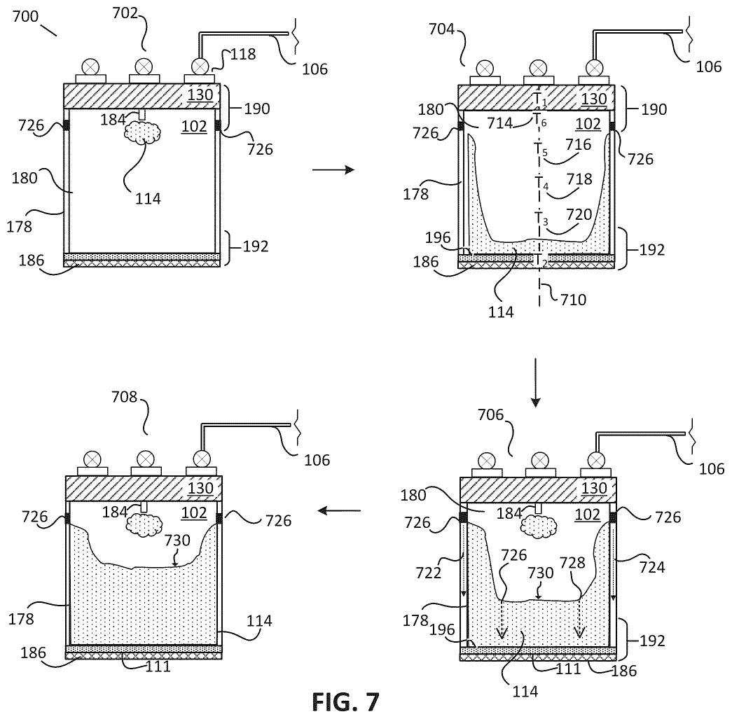

FIG. 7 illustrates an example bulk refilling process 700.

Example temperatures provided herein are for illustrative purposes only and are not intended to limit claimed subject matter. Representative temperatures are for a chemical 114 whose condensation temperature is about 150 C.

In an example, a thermal break 726 may be placed at the top portion 190 of delivery vessel 102. As noted, delivery vessel may be heated by any of a variety of heating devices in top portion 190 (as described in detail above with reference to FIGS. 1-4) and may be actively cooled by any of a variety of cooling devices (as described in detail above with reference to FIG. 1-4).

Again, to facilitate condensation of chemical 114 in the actively cooled area of delivery vessel 102, thermal break 726 may be disposed in delivery vessel 102 at top portion 190.

Bulk refilling process 700 starts as illustrated schematically in stage 702, with chemical 114 entering interior volume 180 of delivery vessel 102 in gaseous form. Chemical 114 flows into interior volume 180 through heated lid 130 via heated chemical line 106. As chemical 114 continues to flow into delivery vessel 102, chemical 114 begins to deposit at base 111 and interior sidewalls 178.

At stage 704, chemical 114 begins to accumulate at base 111 and on interior walls 178 within interior volume 180 of delivery vessel 102. Thermal break 726 is disposed near top portion 190 of delivery vessel 102. A temperature gradient 710 extends along the length of delivery vessel 102 in the longitudinal direction from a higher temperature T1 (e.g., about 170° C.) at top portion 190 to a lower temperature, T2, (e.g., about 130° C.) at bottom portion 192.

In an example, thermal break 726 may not completely insulate the area below the thermal break 726. Rather, the temperature may gradually decrease from top portion 190 longitudinally toward bottom portion 192 creating a temperature gradient 710. Temperature T5 may be between temperature T1 and temperature T2 (e.g., about 150° C.), temperature T4 may be between temperature T5 and temperature T3 (e.g., about 140° C.) and temperature T3 may be closer to temperature T2 (e.g., about 130° C.) as gradient 710 moves farther from thermal break 720 longitudinally. Temperatures T5, T4, and T3 may all be below the condensation temperature of chemical 114 facilitating condensation of chemical 114 at the sidewalls 178 and bottom surface 196.

At stage 706, as chemical 114 continues to condense within delivery vessel 102, solid chemical 114 may build up on sidewalls 178 and from bottom surface 196. Interior sidewalls 178 may be at or below a condensation temperature of chemical 114 due to dissipation of heat below thermal break 726 through delivery vessel 102 to cooled bottom portion 192. Arrows 722 and 724 point in the direction of dissipation of heat through interior sidewalls 178.

Heat also dissipates through chemical 114 from the surface 730 to base 111. Dotted arrows 726 and 728 point in the direction of dissipation of heat through solidified chemical 114. The condensation rate and thickness of chemical 114 will be greater near bottom portion 192 and lower portion of interior sidewalls 178 than the condensation rate and thickness of chemical 114 nearer the thermal break 726 which will grow more slowly and be thinner than solidified chemical 114 lower in delivery vessel 102 at any point in time. Chemical 114 may have a maximum fill height in delivery vessel 102 that directly correlates to the height at which a thermal break is placed. Thus, the fill height of delivery vessel 102 having thermal break 726 is higher than the fill height of delivery vessel 102 having thermal break 109 (see FIG. 5). Still heat dissipation through chemical 114 may slow as the condensed thickness grows, the heat transfer through chemical 114 will become increasingly difficult. At this point, surface 730 may reach a temperature close to or above the condensation temperature of chemical 114 causing condensation of chemical 114 to slow or cease and for solid chemical 114 to stop filling delivery vessel 102.

Moving to stage 708, in an example, reducing the base 111 temperature may reduce the temperature of chemical 114 surface 730 and reinitiate (or further enable) condensation of chemical 114 with in vessel 102. Continuing with the above example temperatures, surface 730 may near 150° C. when condensation slows or ceases. Lowering base 111 temperature, for example, from about 130° C. to about 110° C. may cool surface 730 and may re-initiate condensation allowing solidified chemical 114 volume to reach a new height. As the temperature of base 111 is lowered the resultant cooling may extend through delivery vessel 102 sidewalls 178 into lid 130, valves 184 and 118 and/or chemical delivery line 106. Clogging of these and other components could occur due to condensation when the temperature falls.

FIG. 8 illustrates an example delivery vessel 102 including heat transfer members 802 coupled to base 111. Thermal conductivity of powder chemical 114 may be lower than material the delivery vessel 102 is made of such as stainless steel. In an example, one or more heat transfer members 802 may be coupled to base 111 to improve thermal conductivity through chemical 114. Heat transfer members 802 may provide shorter paths for heat diffusion through powder chemical 114 to cool surface 730. Heat transfer members 802 may be individual members each connected to base 111. Alternatively, members 802 may be connected about a common member base (not shown) configured to couple to base 111. Heat transfer members 802 may comprise fins, round rods, polygonal pegs, or the like or any of a variety of heat transfer devices known to those of skill in the art, or combinations thereof. Contrasting arrows 804 indicate the direction of heat transfer from chemical 114 to heat transfer members 802. Arrows 806 indicate the direction of heat transfer longitudinally along heat transfer members 802 from the top of heat transfer members 802 to base 111. Heat transfer members 802 may be made of a variety of thermally conductive materials such as stainless steel, aluminum, titanium, and/or tungsten, or the like or combinations thereof.

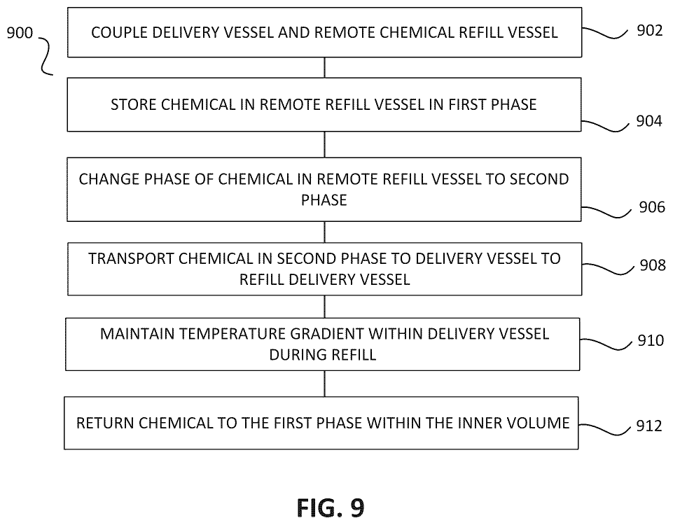

FIG. 9 is a flow chart that depicts an embodiment of a solid source refill process 900, generally. Process 900 will be described with reference to FIGS. 1-2. Process 900 may be controlled by controller 156. Process 900 may begin at block 902, where delivery vessel 102 (see FIG. 1) may be coupled to a remote refill vessel 104. Delivery vessel 102 may be disposed at a first location on a substrate processing platform 110 and remote refill vessel 104 may be disposed in a second location remote from the substrate processing platform 110. In an example, the first location may be separated from the second location by a distance of about 1 ft. to about 20 ft., 20 ft. to about 100 ft., 100 ft. to about 200 ft., or 200 ft. to about 500 ft. Other distances are possible and claimed subject matter is not limited in this regard.

Delivery vessel 102 may be coupled to remote refill vessel 104 via chemical delivery line 106. Process 900 may move to block 904, where a chemical 114 (e.g., precursor) may be stored in remote refill vessel in a first phase. In an example, first phase may be solid phase. In another example, the first phase may be liquid or gas. At block 906, the phase of chemical 114 may be changed to a second phase by action of one or more components of remote refill vessel 104. Such action may comprise heating and/or pressurizing chemical 114. In an example, the first phase and the second phase are different. Process 900 may move to block 908 where chemical 114 may be transported to delivery vessel 102 in the second phase to refill delivery vessel 102 with chemical 114. Chemical 114 may be transported from remote refill vessel 104 to delivery vessel 102 by opening of chemical delivery line 106 wherein open chemical delivery line 106 puts the remote refill vessel 104 in fluid communication with the delivery vessel. At block 910 a temperature gradient within delivery vessel 102 may be maintained. In an example, controller 156 may be coupled to heating device 176, cooling device 186 and one or more sensors disposed within inner volume 180. Controller 156 may be configured to control temperatures of heating device 176 and/or cooling device 186 responsive to sensor data received from one or more sensors (e.g., sensors 210, 306, 308, and/or 310). At block 912, chemical 114 may be returned to the first phase (e.g., solidified) within inner volume 180 at least on a bottom surface 414 (see FIG. 4) of the delivery vessel 102.

One or more actions described in blocks 902, 904, 906, 908, 910 and/or 912 may be executed simultaneously and/or sequentially. After refill is complete chemical 114 may be transported to other components such as accumulator 101 or reaction chamber 138 and/or 140 in fluid communication with delivery vessel 102 to process one or more substrates 146 and/or 148.

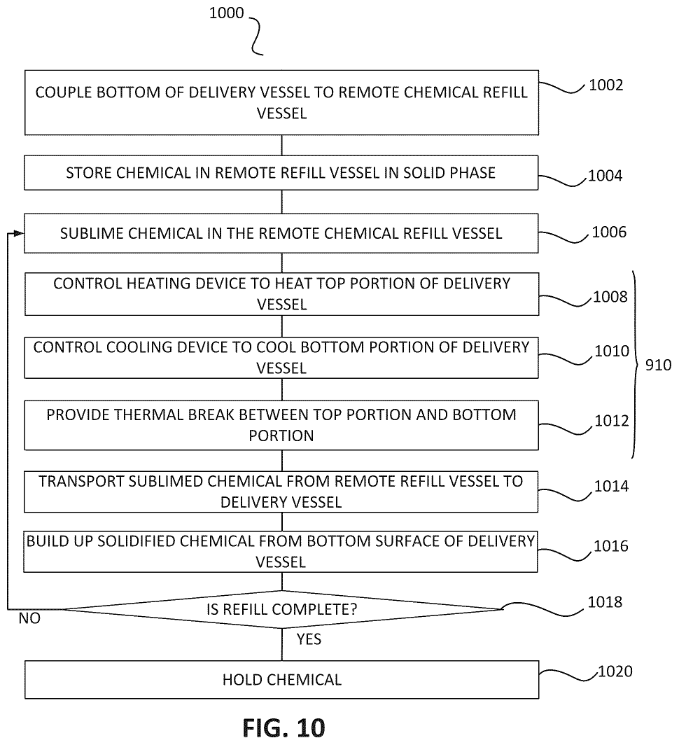

FIG. 10 is a flow chart that depicts an example process 1000 which is an example embodiment of a solid source refill process 900 shown in FIG. 9. In an example, process 1000 will be described with reference to FIGS. 1-9. Process 1000 may be controlled by controller 156. Process 1000 may begin at block 1002, where delivery vessel 102 (see FIG. 1) may be coupled at a top portion 190 to a remote refill vessel 104 via a chemical delivery line 106. Delivery vessel 102 may be disposed at a first location on a substrate processing platform 110 and remote refill vessel 104 may be disposed in a second location remote from the substrate processing platform 110. Process 1000 may continue at block 1004, where a solid chemical 114 (e.g., precursor) may be stored in solid phase in remote refill vessel 104 at a first temperature below the condensation temperature of chemical 114. At block 1006, chemical 114 may be sublimed within remote refill vessel 104 at a second temperature above the condensation temperature by exposing chemical 114 to heat and/or pressure to convert the solid to a gas.

In an example, block 910 (see FIG. 9) “maintain temperature gradient within delivery vessel” may comprise block 1008, block 1010 and/or block 1012.

At block 1008, controller 156 may maintain temperature gradient 324 by heating top portion 190 of delivery vessel 102 by controlling heating device 176 responsive to sensor data received from one or more temperature sensors 210, 306, 308, and/or 310 (see FIG. 3), within delivery vessel 102. In an example, controlling heating device 176 may be based on comparison of the sensor data to a temperature gradient profile stored in memory 168 corresponding to delivery vessel 102 identifying a predetermined first temperature and/or first threshold temperature range for at least top portion 190. Maintaining temperature gradient 324 (see FIG. 3) may further comprise holding top portion 190 at about the first temperature.

At block 1010, controller 156 may maintain temperature gradient 324 by cooling bottom portion 192 of delivery vessel 102 by controlling cooling device 186 responsive to sensor data received from one or more temperature sensors 210, 306, 308, and/or 310, within delivery vessel 102. In an example, controlling cooling device 186 may be based on comparison of the sensor data to a temperature gradient profile stored in memory 168 corresponding to delivery vessel 102 identifying a predetermined second temperature and/or second threshold temperature range for at least bottom portion 192. Maintaining temperature gradient 324 may further comprise holding bottom portion 192 at about the second temperature.

In an example, the first temperature may be higher than the second temperature. For example, the first temperature may be higher that a sublimation temperature of chemical 114 and the second temperature may be below a condensation temperature of chemical 114.

At block 1012, maintaining the temperature gradient 324 further comprises providing a thermal break 109 between top surface 113 and bottom surface 196 (see FIG. 1) of delivery vessel 102. In an example, the position of the thermal break 109 may influence the way chemical 114 solidifies within delivery vessel 102. Thermal break 109 may be disposed in an upper half or a lower half of the delivery vessel with respect to a longitudinal axis extending from the top surface of delivery vessel 102 to the bottom surface.

At block 1016, chemical 114 may be transported to top portion 190 of delivery vessel 102 in gas phase to refill delivery vessel 102.

At block 1014, sublimed chemical 114 may be transported to remote refill vessel 102 to delivery vessel 102. At block 1016, chemical 114 solidify and build up upon bottom surface 196 within the interior volume 180 of delivery vessel 102. At block 1018, it may be determined by controller 156 whether delivery vessel 102 refill is complete, for example, if chemical 114 solid has grown to a predetermined height. Controller 156 may maintain a temperature gradient within an inner volume 180 of the delivery vessel 102 to promote growth of the chemical 114 solid mass for example, by maintaining a temperature of bottom surface 196 below a condensation temperature of chemical 114. Process 1000 may continuously return to block 1006 until delivery vessel 102 is refilled. Blocks 1006-1018 may be performed simultaneously during filling process. Process 1000 moves to block 1020 upon completion of the refilling of delivery vessel 102 with chemical 114. At block 1020, solidified chemical 114 may be held in delivery vessel 102 until use in a material processing operation. Blocks 1002-1020 may be executed simultaneously or in sequence.

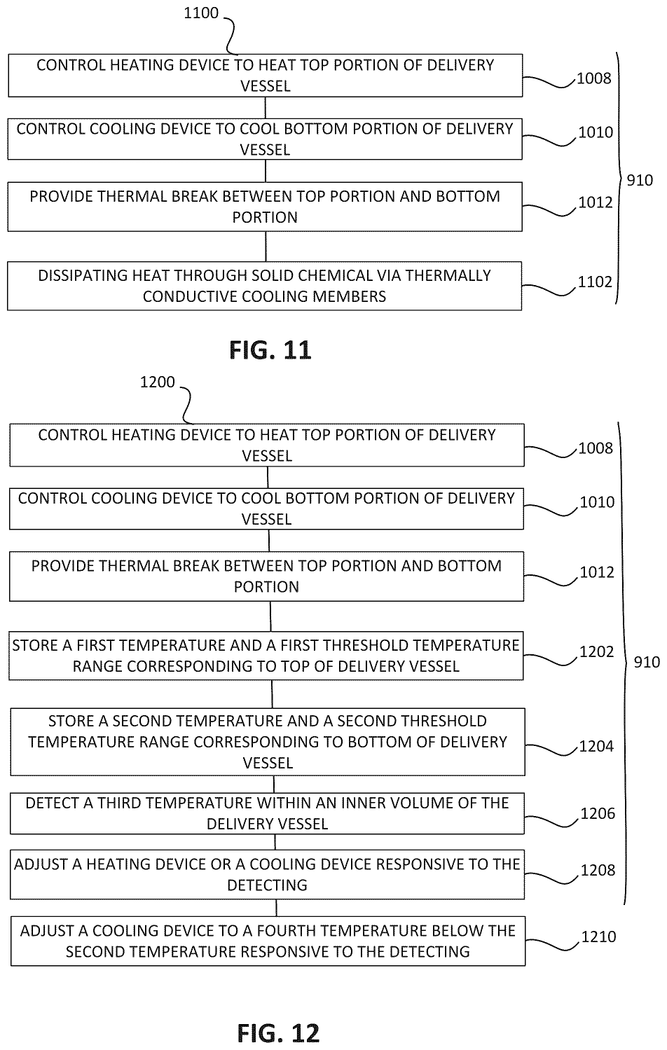

FIG. 11 is a flow chart illustrating an example process 1100 which is an example stage of solid source refill process 900 at block 910 (see FIG. 9). Process 1100 may be controlled by controller 156. Process 1100 will be described with reference to FIGS. 1-9.

At block 1008, a heating device 176 may be controlled by controller 156 to heat top portion 190 of delivery vessel 102. At block 1010, controller 156 may maintain temperature gradient 324 by cooling bottom portion 192 of delivery vessel 102. At block 1012, a thermal break 109 may be provided between top surface 113 and bottom surface 196 (see FIG. 1) of delivery vessel 102. At block 1102, heat may be dissipated through solid chemical 114 via thermally conductive cooling members 406 (see FIG. 4).

FIG. 12 is a flow chart illustrating an example process 1200 which is an example stage of solid source refill process 900 at block 910 shown in FIG. 9. In an example, process 1200 will be described with reference to FIGS. 1-9. Process 1200 may be controlled by controller 156.

At block 1008, heating device 176 may be controlled by controller 156 to heat top portion 190 of delivery vessel 102. At block 1010, controller 156 may maintain temperature gradient 324 by cooling bottom portion 192 of delivery vessel 102. At block 1012, a thermal break 109 may be provided between top surface 113 and bottom surface 196 (see FIG. 1) of delivery vessel 102. At block 1202, a first temperature and/or a first threshold temperature range corresponding to top portion 190 of delivery vessel 102 may be stored in memory 168. The first temperature may be above a sublimation temperature of chemical 114. In an example, controller 156 may monitor sensor data as described above to determine whether a selected location (e.g., top portion 190) within delivery vessel 102 is within the first threshold temperature range of the first temperature. At block 1204, a second temperature and/or a second threshold temperature range corresponding to bottom portion 192 of delivery vessel 102 may be stored in memory 168. The second temperature may be equal to or below a sublimation temperature of chemical 114. In an example, controller 156 may monitor sensor data as described above to determine whether a selected location (e.g., bottom portion 192) within delivery vessel 102 is within the second threshold temperature range of the second temperature.

At block 1206, a third temperature may be detected within an inner volume of the delivery vessel 102. Detecting may be executed by sensors 210, 306, 308, and/or 310. If temperature data from sensors 210, 306, 308, and/or 310 indicates that temperatures in selected locations (e.g., top portion 190 and/or bottom portion 192) are outside of an identified temperature range (e.g., first and/or second threshold temperature range), controller 156 may take action at block 1208, wherein controller 156 may adjust heating device 176 or cooling device 186 responsive to the detecting.

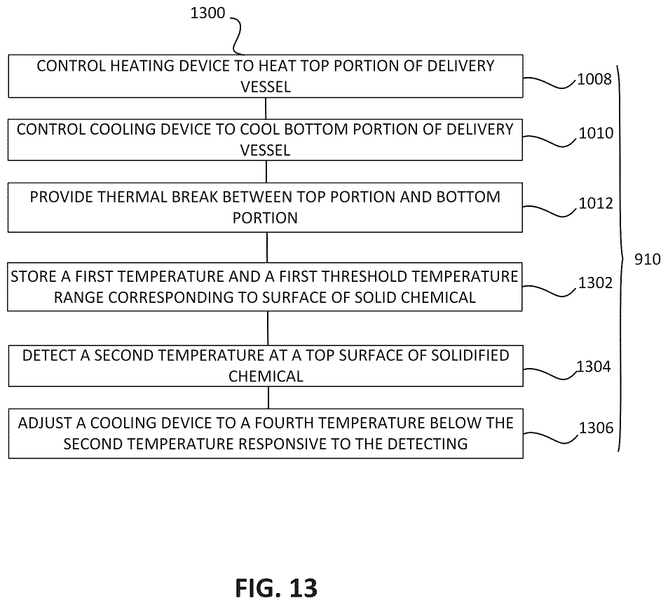

FIG. 13 is a flow chart that depicts an example process 1000 which is an example embodiment of a solid source refill process 900 shown in FIG. 9. In an example, process 1000 will be described with reference to FIGS. 1-9. Process 1300 may be controlled by controller 156.

At block 1008, heating device 176 may be controlled by controller 156 to maintain temperature gradient 324 by heating top portion 190 of delivery vessel 102. At block 1010, controller 156 may maintain temperature gradient 324 by cooling bottom portion 192 of delivery vessel 102. At block 1012, a thermal break 109 may be provided between top surface 113 and bottom surface 196 of delivery vessel 102. At block 1302, a first temperature and/or a first threshold temperature range corresponding to surface 526 of solidified chemical 114 may be stored in memory 168. At block 1304, a second temperature may be detected on a surface 526 of solidified chemical 114. Detecting may be executed by sensors 210, 306, 308, and/or 310 or the like. If temperature data from sensors 210, 306, 308, and/or 310 or the like indicates that the temperature at surface 526 is outside of an identified temperature range (e.g., first threshold temperature range), controller 156 may take action at block 1306, wherein controller 156 may adjust cooling device 186 to a lower temperature to bring down the temperature of surface 526 to reinitiate condensation of chemical 114 which may have stalled sue to an increase in temperature at surface 526.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The headings provided herein, if any, are for convenience only and do not necessarily affect the scope or meaning of the devices and methods disclosed herein.

1. A method, comprising:
coupling a delivery vessel disposed at a first location on a substrate processing platform to a remote refill vessel disposed in a second location remote from the substrate processing platform;
storing a chemical in the remote refill vessel in a first phase;
changing the chemical in the remote refill vessel to a second phase;
transporting the chemical in the second phase, to the delivery vessel;
maintaining a temperature gradient within an inner volume of the delivery vessel; and
returning the chemical to the first phase within the inner volume.

2. The method of claim 1, wherein the first phase is a solid and the second phase is a gas and wherein the maintaining the temperature gradient further comprises:
controlling a heating device disposed at a top portion of the delivery vessel or controlling a cooling device disposed at a bottom portion of the delivery vessel or a combination thereof, responsive to sensor data received from one or more temperature sensors inside the delivery vessel; and
solidifying the chemical within the inner volume at least at a bottom surface of the delivery vessel.

3. The method of claim 2, wherein the controlling the heating device disposed at the top portion of the delivery vessel or controlling the cooling device disposed at the bottom portion of the delivery vessel or a combination thereof, is further based on comparison of the sensor data to a profile corresponding to the delivery vessel identifying a predetermined first temperature and first threshold temperature range for at least a top portion of the delivery vessel and a predetermined second temperature and second threshold temperature range for at least a bottom portion of the delivery vessel.

4. The method of claim 3, wherein the first temperature is higher than the second temperature.

5. The method of claim 3, wherein the first temperature is higher than the sublimation temperature of the chemical and the second temperature is below a condensation temperature of the chemical.

6. The method of claim 1, wherein maintaining the temperature gradient further comprises:
holding a top portion of the delivery vessel at a first temperature above a phase change temperature of the chemical and holding a bottom portion of the delivery vessel at a second temperature below a phase change temperature of the chemical; and
providing a thermal break between the top portion of the delivery vessel and the bottom portion of the delivery vessel.

7. The method of claim 1, wherein maintaining the temperature gradient further comprises providing a thermal break between a top portion of the delivery vessel and a bottom portion of the delivery vessel.

8. The method of claim 7, wherein the thermal break is disposed in a lower half of the delivery vessel with respect to a longitudinal axis extending from a top surface of the delivery vessel to a bottom surface of the delivery vessel.

9. The method of claim 7, wherein the thermal break is disposed in an upper half of the delivery vessel with respect to a longitudinal axis extending from a top surface of the delivery vessel to a bottom surface of the delivery vessel.

10. The method of claim 1, wherein maintaining the temperature gradient further comprises dissipating heat through the chemical after solidification of the chemical at a bottom surface of the delivery vessel via thermally conductive cooling members thermally coupled to a base of delivery vessel.

11. The method of claim 1, wherein maintaining the temperature gradient further comprises:
storing, in a controller memory, a first temperature and a first threshold temperature range corresponding to at least a top portion of the delivery vessel;
storing, in the controller memory, a second temperature and a second threshold temperature range corresponding to at least a bottom portion of the delivery vessel, wherein the first temperature is higher than the second temperature;
detecting a third temperature within the inner volume of the delivery vessel; and
adjusting a heating device or a cooling device responsive to the detecting.

12. The method of claim 11, wherein the detecting the third temperature further comprises:
detecting the third temperature at a top surface of solidified chemical on a bottom surface of the delivery vessel is above a threshold temperature; and
adjusting the cooling device to a fourth temperature below the second temperature responsive to the detecting.

13. A substrate processing system, comprising:
a delivery vessel, disposed in a first location on a substrate processing platform;
a remote refill vessel in fluid communication with the delivery vessel via a chemical delivery line, the remote refill vessel disposed in a second location remote from the substrate processing platform;
a heating device in thermal communication with a top surface of the delivery vessel;
a cooling device in thermal communication with a bottom surface of the delivery vessel;
a thermal break disposed between the top surface and the bottom surface;
a sensor located within an inner volume of the delivery vessel; and
a controller coupled to the sensor, the heating device and the cooling device configured to control the heating device and the cooling device responsive to the sensor so as to maintain a temperature gradient within the delivery vessel.

14. The substrate processing system of claim 13, further comprising one or more cooling members thermally coupled to a base of the delivery vessel.

15. The substrate processing system of claim 14, wherein the one or more cooling members comprise rods, fins, or pegs, or a combination thereof.

16. The substrate processing system of claim 13, wherein the thermal break is a vacuum section within a wall of the delivery vessel.

17. The substrate processing system of claim 13, wherein the thermal break is disposed in a top half of the delivery vessel with respect to a longitudinal axis.

18. The substrate processing system of claim 13, wherein the thermal break is disposed in a bottom half of the delivery vessel with respect to a longitudinal axis.

19. The substrate processing system of claim 13, wherein the heating device comprises a heater, a heating jacket, a heating block, or a radial heater, or a combination thereof.

20. The substrate processing system of claim 13, wherein the cooling device comprises a cooling coil, an integrated cooling channel, a cooling member, a cooling jacket, or a cold plate, or a combination thereof.

21. The substrate processing system of claim 13, further comprising a plurality of sensors, wherein data from each of the plurality of sensors includes associated location data.
